(19) United States
(12) Patent Application Publication
(10) Pub. No.: US 2025/0096788 A1
(43) Pub. Date: Mar. 20, 2025

(54) Advanced Phase-Leg Short-Circuit Protection for Third-Generation Semiconductors

(71) Applicant: Hong Kong Applied Science and Technology Research Institute Company Limited, Hong Kong (HK)

(72) Inventors: Kai Wing Andy YEUNG, Hong Kong (HK); Sui Pung CHEUNG, Hong Kong (HK); Changqing YIN, Hong Kong (HK); Tin Ho LI, Hong Kong (HK)

(21) Appl. No.: 18/469,502

(22) Filed: Sep. 18, 2023

(51) Int. Cl. H03K 17/08

(52) U.S. Cl. CPC H03K 17/08; H02M 1/38

(57) ABSTRACT

Shoot-through current flows when a pull-up transistor and a pull-down transistor in series both turn ON at the same time, such as due to noise. The transistor that should be OFF has an OFF drain-source voltage that is high when the other transistor is ON, but quickly falls when the OFF transistor erroneously turns on. A shoot-through protection circuit compares the OFF drain-source voltage of the OFF transistor to a reference voltage. When the OFF drain-source voltage falls below the reference voltage, a fault is signaled. The fault signal immediately disables the ON transistor by driving its gate inactive (low) to stop the shoot-through current. The reference voltage may be a fraction of the power voltage, such as 30% of a 400-volt input power bus, providing over 100 volts noise immunity, preventing false triggering yet immediately blocking current when the reference voltage is passed without waiting for a blanking period.

### FIELD OF THE INVENTION

This invention relates to short-circuit protection circuits, and more particularly to detecting turn-on of the off device in a push-pull leg.

### BACKGROUND OF THE INVENTION

Power devices often use a pull-up transistor and a pull-down transistor in each leg of a full bridge, a half bridge, or a multi-phase multi-leg device. These transistors can be standard silicon Metal-Oxide-Semiconductor Field-Effect Transistors (MOSFETs) or can be made from more advanced materials such as Gallium-Arsenic Nitride (GaN) or Silicon Carbide (SiC).

FIG. 1 shows a prior-art Switched-Mode Power Supply (SMPS). An input supply voltage VIN+ is to be converted to an output supply voltage VOUT+. A common ground GND is used for both input and outputs, but some systems have separate grounds.

Input capacitor 320 between VIN+ and GND filters the input to the drains of pull-up transistors 302, 306, while ground is connected to the sources of pull-down transistors 304, 308. The source of pull-up transistor 302 and the drain of pull-down transistor 304 are connected together to drive VOUT+ through inductor 312 to charge output capacitor 330.

The gate G1 of pull-up transistor 302 is driven high to turn on transistor 302 for a period of time to charge output capacitor 330. Once G1 is driven low, the gate of pull-down transistor 304 is driven high to discharge output capacitor 330. The signals for G1, G2 are typically clocks in the kHz frequency range, and the duty cycles are adjusted to obtain the desired output voltage VOUT+ for a particular input voltage VIN+. For example, by increasing the high time (duty cycle) for G1 relative to that of G2, a higher VOUT+ may be obtained.

Similarly, the source of pull-up transistor 306 and the drain of pull-down transistor 308 are connected together to drive VOUT+ through inductor 314 to charge output capacitor 330. The switching signals applied to the gates of transistors 306, 308 can be 180 degrees out-of-phase with the switching signals driving the gates of transistors 302, 304 for reduced output ripple.

Transistors 302, 304, 306, 308 could be n-channel Metal-Oxide-Semiconductor Field-Effect Transistors (MOSFET), but more recently Gallium-Nitride (GaN) transistors or Silicon Carbide (SiC) are being used since they can supply a much higher current for a given physical transistor size. GaN and SiC transistors have allowed for higher density power-converter modules, since a higher power current can be provided using GaN or SiC devices for a given size. The smaller input capacitance of GaN and SiC transistors compared to MOS transistors provides a faster switching response time that can enable higher frequency applications. Lower switching loss can result in better efficiency.

These more advanced devices such as SiC and GaN have very fast switching and low turn-on impedances. While these properties make SiC and GaN ideal for fast high-current devices, these same properties make them especially vulnerable to short circuits that can burn out components and cause downstream systems to collapse. For example, when pull-down transistor 304 is on and pull-up transistor 302 is off, noise such as ground bounce might couple into the driver that generates gate node G1, causing G1 to glitch high, turning on pull-up transistor 302. Then a short-circuit path from VIN+ to GND is established through transistors 302, 304 which are both on. An extremely high current can flow, possibly burning out components and discharging capacitor 320, causing VIN+ to fall.

A traditional short-circuit protection method for a single transistor is known as DeSaturation protection (DESAT). A voltage-sensing pin is added to detect the drain-to-source (or collector-emitter) voltage of the ON transistor. When turned ON, the transistor normally operates in the saturation region. However, when the current exceeds the maximum allowed current, the transistor is over-saturated and device failure can occur. The over-saturated current causes a high Vds voltage drop across the transistor since Vds=I*R. This high Vds voltage drop can be detected by a DESAT detector and used to shut off the ON transistor.

However, during normal switching some oscillation can occur on the outputs and across Vds. This oscillation can falsely trigger the DESAT protection circuit, potentially shutting down the transistor when switching occurs. To prevent this false triggering, a filter is added to the DESAT circuit to create a blanking time to disable DESAT during switching. This blanking time can fairly large, such as 2.5 usec.

DESAT both detects and protects the same transistor. When the transistor is ON, a large current normally flows through the transistor. As over-saturation occurs, the IR drop increases until the threshold for Vds is reached to trigger DESAT protection. However, the filter delays the start of protection by the blanking time, so current can continue to increase during this blanking time. Once the blanking time expires the transistor can be turned off.

Higher current and higher speed applications require a larger blanking time to prevent false triggers. But this blanking time delays protection, possibly allowing the short current to flow for a long enough period of time to burn out components.

What is desired is a short-circuit protection circuit that does not have a blanking time. A protection circuit that does not require a filter that delays protection but still prevents false triggering is desired. A protection circuit that detects a larger-voltage signal than DESAT is desired to improve noise immunity and allow the filter to be reduced or removed. Improving the response time of a protection circuit is desired.

### BRIEF DESCRIPTION OF THE DRAWINGS

FIG. 1 shows a prior-art Switched-Mode Power Supply (SMPS).

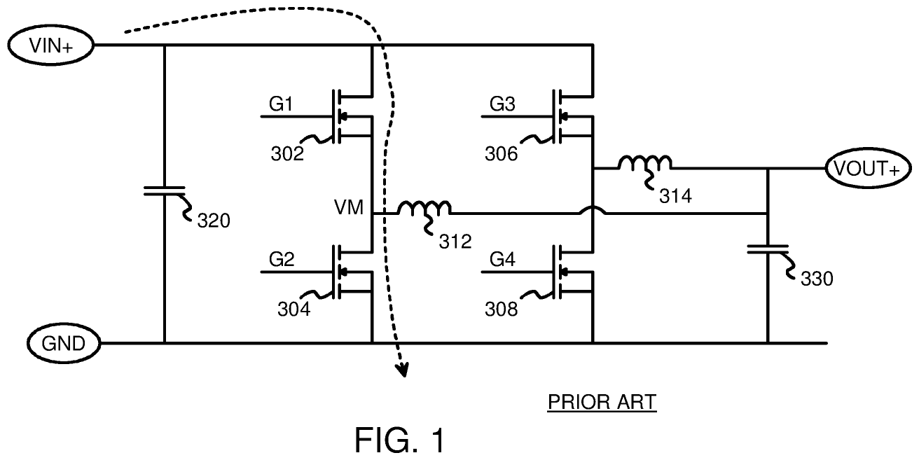

FIG. 2 highlights short-circuit detection using the OFF transistor.

FIG. 3 shows a dual-transistor package with Kelvin sensing paths.

FIG. 4 shows a detection circuit.

FIG. 5 shows short protection by pull-up Vds detection.

FIG. 6 shows short protection by pull-down Vds detection.

FIG. 7 is a truth table showing operating modes and short conditions for the short protection circuit.

FIG. 8 is a flowchart of detection of a falling drain-source voltage on the OFF transistor to turn off the ON transistor for short protection.

FIG. 9 is a waveform of operation of the short detection circuit.

FIG. 10 is an alternative short detection circuit when a Kelvin drain is not available.

FIG. 11 is another alternative short detection circuit when a Kelvin drain is not available.

FIG. 12 shows a capacitor-divider detection circuit.

FIG. 13 shows an opto-isolated detection circuit.

FIG. 14 shows a transformer-isolated detection circuit.

### DETAILED DESCRIPTION

The present invention relates to an improvement in short protection circuits. The following description is presented to enable one of ordinary skill in the art to make and use the invention as provided in the context of a particular application and its requirements. Various modifications to the preferred embodiment will be apparent to those with skill in the art, and the general principles defined herein may be applied to other embodiments. Therefore, the present invention is not intended to be limited to the particular embodiments shown and described but is to be accorded the widest scope consistent with the principles and novel features herein disclosed.

While DESAT protection circuits measure the voltage drop of the same transistor (ON transistor) that is then turned OFF and protected, the inventor instead detects the voltage across the OFF transistor and uses the OFF transistor Vds voltage to turn off the ON transistor. Thus, separate detection and protection transistors are used.

The inventor has recognized that the ON transistor has a low ON resistance, and thus a current change generates a relatively small voltage change since Vds=Ids*Ron. In contrast, the OFF transistor has a high OFF resistance, Roff>Ron. The inventor realizes that the OFF transistor has an inherently higher Roff and therefore a higher Vds change than does the ON transistor, so the OFF transistor produces a larger voltage for detection.

Parasitic inductances produce a large voltage drop when current changes quickly (di/dt). Parasitic inductances such as from devices package pins and leads, and wiring traces can also generate a large voltage drop when the short current begins to flow and di/dt is large. Detection can use a combination of the di/dt voltage drops on the parasitic inductances and the Vds drop of the actual transistor channel.

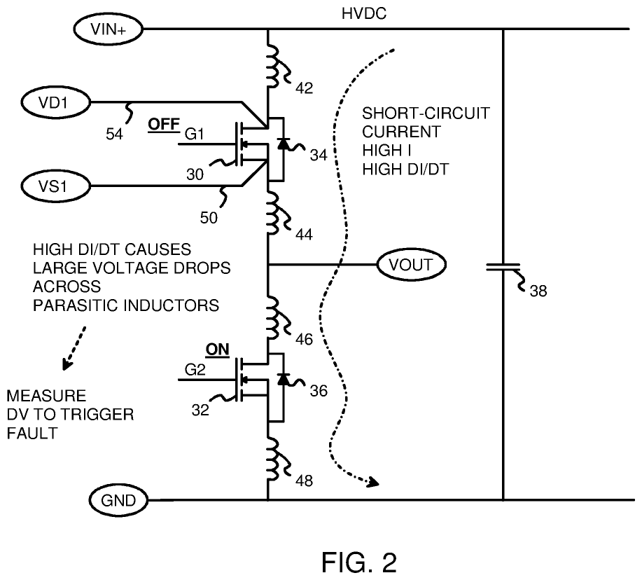

FIG. 2 highlights short-circuit detection using the OFF transistor. Pull-up transistor 32 is OFF and pull-down transistor 30 is ON. However, noise causes gate signal G1 to glitch high, turning on pull-up transistor 32 which should be OFF. Current can flow from VIN+ to GND through transistors 30, 32. Current also flows through parasitic inductances, such as inductors 42, 44, 46, 48. Capacitor 38 may discharge to supply current in excess of what is applied to VIN+. Advanced transistors such as SiC and GaN devices may have body diodes 34, 36 that are parallel to their conducting channels.

As the short current begins to flow from VIN+ to GND, di/dt is very high due to the sudden change in current, causing a large voltage drop across inductors 42, 44. When pull-up transistor 32 is OFF, it has a high voltage drop Vds, but Vds drops as current starts to flow through pull-up transistor 32 and the voltage drop is transferred from pull-up transistor 32 to inductors 42, 44.

This decline in Vds across pull-up transistor 32 can be detected and used to turn off pull-down transistor 30. Thus, Vds collapse is detected across OFF pull-up transistor 32 and used to turn off G2 to ON pull-down transistor 30. When pull-down transistor 30 is shut off, the short current stops flowing, protecting both pull-down transistor 30 and pull-up transistor 32.

Rather than detect an increase in Vds in the ON transistor, as in DESAT protection, the inventor detects a decrease in Vds on the OFF transistor.

The voltage across pull-down transistor 30, Vds, can be detected independent of the voltage drops across inductors 42, 44 when Kelvin sensing pins are available. For example, a package containing pull-up transistor 32 may provide a Kelvin drain pin VD1 that has Kelvin sensing path 54 from an external pin directly to the drain of pull-up transistor 32. Kelvin sensing path 54 carries a much lower sensing current than the drain current through inductor 42 to the VIN+ pin, so the parasitic inductance is much lower. Also, the device layout may provide a shorter route for Kelvin sensing path 54 than for the drain current path to VIN+ through inductor 42.

Likewise, the device package may include Kelvin sensing path 50 directly to the source of pull-up transistor 32, bypassing inductor 44. Then a detector could sense the drain voltage on VD1 and the source voltage on VS1 to generate the Vds voltage as VD1 VS1.

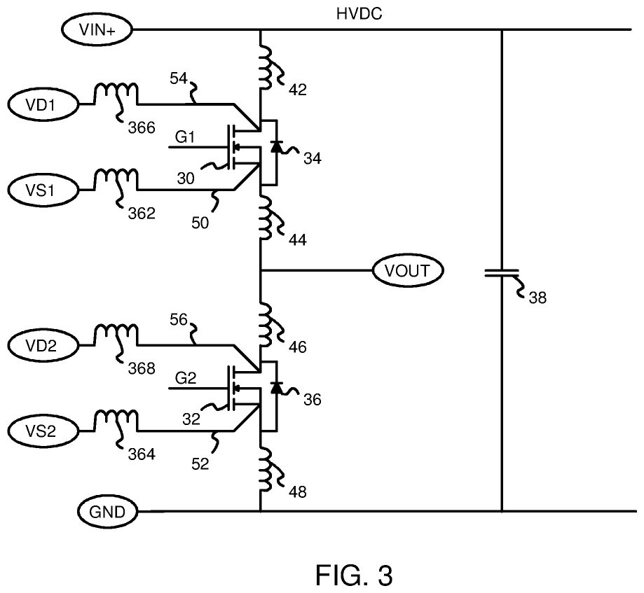

FIG. 3 shows a dual-transistor package with Kelvin sensing paths. A device package may include both pull-down transistor 30 and pull-up transistor 32, with inductor 42 being the package inductance to pin VIN+, inductor 48 being the package inductance to pin GND, inductor 44 being the package inductance from the source of pull-up transistor 32 to output pin VOUT, and inductor 46 being the package inductance from the drain of pull-down transistor 30 to output pin VOUT. Capacitor 38 could be external to the package.

The package also adds four Kelvin sensing pins. Kelvin sensing path 54 connects the drain of pull-up transistor 32 to pin VD1 and has parasitic inductor 366. Kelvin sensing path 50 connects the source of pull-up transistor 32 to pin VS1 and has parasitic inductor 362. Kelvin sensing path 56 connects the drain of pull-down transistor 30 to pin VD2 and has parasitic inductor 368. Kelvin sensing path 52 connects the source of pull-down transistor 30 to pin VS2 and has parasitic inductor 364.

Careful layout within the package and the selection and arrangement of package leads and pins may reduce the parasitic inductances of parasitic inductors 362, 364, 366, 368 relative to that of inductors 42, 44, 46, 48.

Also, the amount of current passing through parasitic inductors 362, 364, 366, 368 may be much less than the current passing through inductors 42, 44, 46, 48. Sensing current can be 1% or less of the switched current to VOUT. Thus, the inductances of parasitic inductors 362, 364, 366, 368 can be negligible.

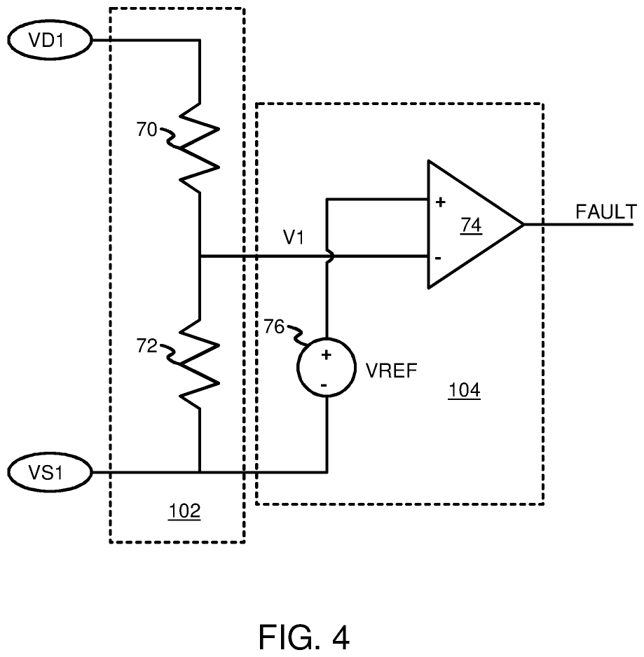

FIG. 4 shows a detection circuit. Detector 102 is a voltage divider of resistors 70, 72 that generate voltage V1 as a midpoint voltage between VD1 and VS1. For example, when the resistances of resistors 70, 72 are equal, then V1=(VD1−VS1)/2+VS1.

Comparator 104 applies midpoint voltage V1 to the inverting (−) input of comparator 74, while the non-inverting (+) input of comparator 74 receives VS1 shifted by reference voltage VREF, using reference voltage generator 76 to add VREF to VS1. Comparator 74 activates its output FAULT when (VS1+VREF) is greater than V1.

Substituting V1=(VD1−VS1)/2+VS1, FAULT is high when:

(VS1+VREF)>(VD1−VS1)/2+VS1

VREF>(VD1−VS1)/2

More generically, when the resistance ratio R of resistors 70, 72, and R=R72/(R70+R72), then:

VREF>(VD1−VS1)*R

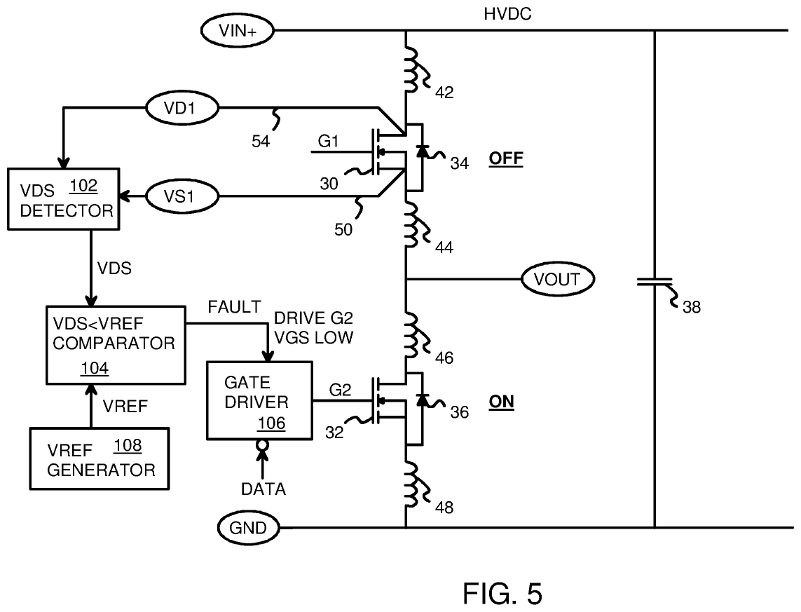

FIG. 5 shows short protection by pull-up Vds detection. When pull-up transistor 32 is ON and pull-down transistor 30 is OFF, detection is performed using Kelvin sensing paths 50, 54 to the source and drain of pull-up transistor 32, the OFF device. Detector 102 senses drain voltage VD1 from Kelvin sensing path 54 and source voltage VS1 from Kelvin sensing path 50 and generates VDS. Comparator 104 compares VDS to reference voltage VREF and activates FAULT when VDS is less than VREF.

When pull-up transistor 32 is OFF, its VDS is large, since its drain is pulled high to VIN+ and its source is pulled low to VOUT, which is being pulled low by pull-down transistor 30 being ON.

When a short occurs and current flows through pull-up transistor 32, the high di/dt causes large voltage drops to occur on inductors 42, 44, reducing VDS across pull-up transistor 32. Pull-up transistor 32 turning on causes its drain and source voltages to equalize, also causing VDS to drop toward zero.

Reference generator 108 generates VREF to a value that is less than VDS when pull-up transistor 32 is OFF. As VDS drops due to the short circuit current, once VDS is less than VREF, FAULT is activated by comparator 104 and gate driver 106 then drives gate G2 low to turn off pull-down transistor 30. Once pull-down transistor 30 turns off, then the short current stops flowing from VIN+ to ground GND.

Gate driver 106 can be a standard pre-driver buffer that receives inverse data as an input and drives gate G2 high when DATA is low, causing VOUT to fall. FAULT can be an inverse enable (ENB) input to gate driver 106 that forces G2 low when ENB is high.

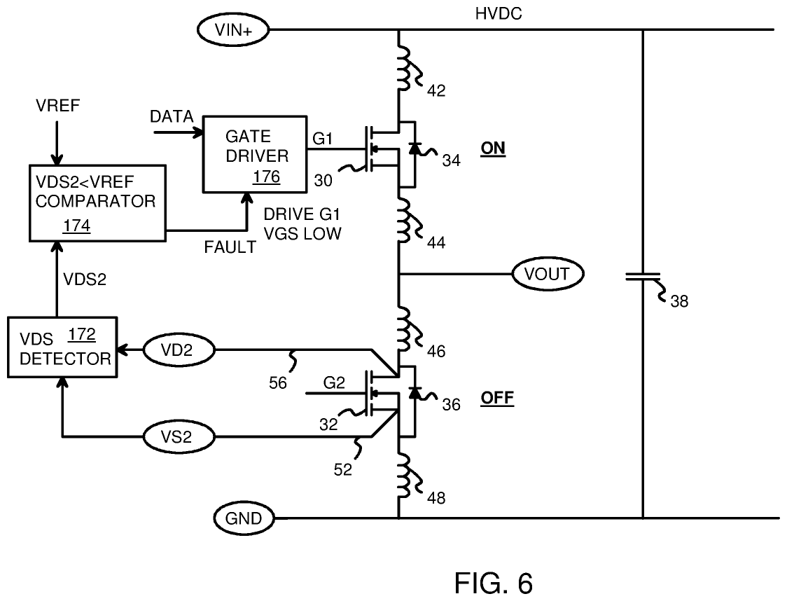

FIG. 6 shows short protection by pull-down Vds detection. When pull-up transistor 32 is OFF and pull-down transistor 30 is ON, detection is performed using Kelvin sensing paths 52, 56 to the source and drain of pull-down transistor 30, the OFF device. Detector 172 senses drain voltage VD2 from Kelvin sensing path 56 and source voltage VS2 from Kelvin sensing path 52 and generates VDS2. Comparator 174 compares VDS2 to reference voltage VREF and activates FAULT when VDS2 is less than VREF.

When pull-down transistor 30 is OFF, its VDS2 is large, since its source is pulled low to ground and its drain is pulled high to VOUT, which is being pulled high by pull-up transistor 32 being ON.

When a short occurs and current flows through pull-down transistor 30, the high di/dt causes large voltage drops to occur on inductors 46, 48, reducing VDS2 across pull-down transistor 30. Pull-down transistor 30 turning on causes its drain and source voltages to equalize, also causing VDS2 to drop toward zero.

Reference generator 108 (FIG. 5) generates VREF to a value that is less than VDS2 when pull-down transistor 30 is OFF. As VDS2 drops due to the short circuit current, once VDS2 is less than VREF, FAULT is activated by comparator 174 and gate driver 176 then drives gate G1 low to turn off pull-up transistor 32. Once pull-up transistor 32 turns off, then the short current stops flowing from VIN+ to ground GND. Gate driver 176 can be a standard pre-driver buffer that receives data as an input and drives gate G1 high when DATA is high, causing VOUT to rise. FAULT can be an inverse enable (ENB) input to gate driver 176 that forces G1 low when ENB is high.

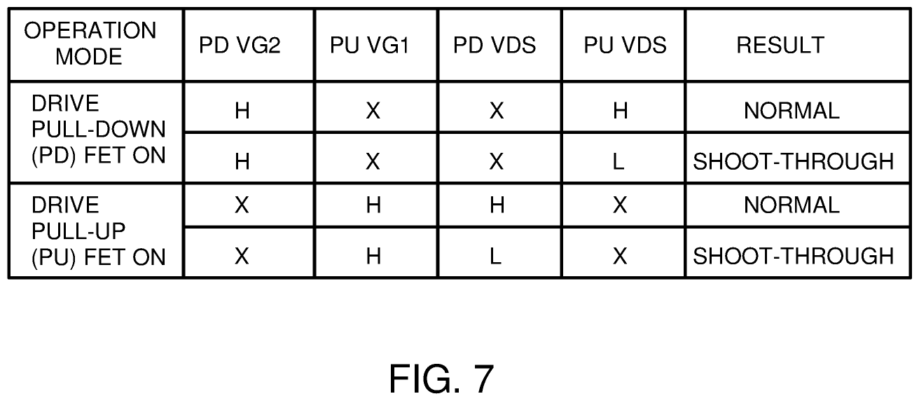

FIG. 7 is a truth table showing operating modes and short conditions for the short protection circuit. There are two operation modes for normal operation:
(1) G2 is driven high to turn ON pull-down transistor 30, as shown in the second column by G2 being driven high H. This is Pull-Down PD mode.
(2) G1 is driven high to turn ON pull-up transistor 32, as shown in the third column by G1 being driven high H. This is Pull-Up PU mode.

In mode (1), PD mode, VDS of the PU transistor, pull-up transistor 32, should be high H, as shown in the fifth column, for normal operation. However, when a short occurs, VDS of the OFF pull-up transistor 32 falls low L, causing detection of the short or shoot-through condition (sixth column).

In mode (2), PU mode, VDS of the PP transistor, pull-down transistor 30, should be high H, as shown in the fourth column, for normal operation. However when a short occurs, VDS of the OFF pull-down transistor 30 falls low L, causing detection of the short or shoot-through condition (sixth column).

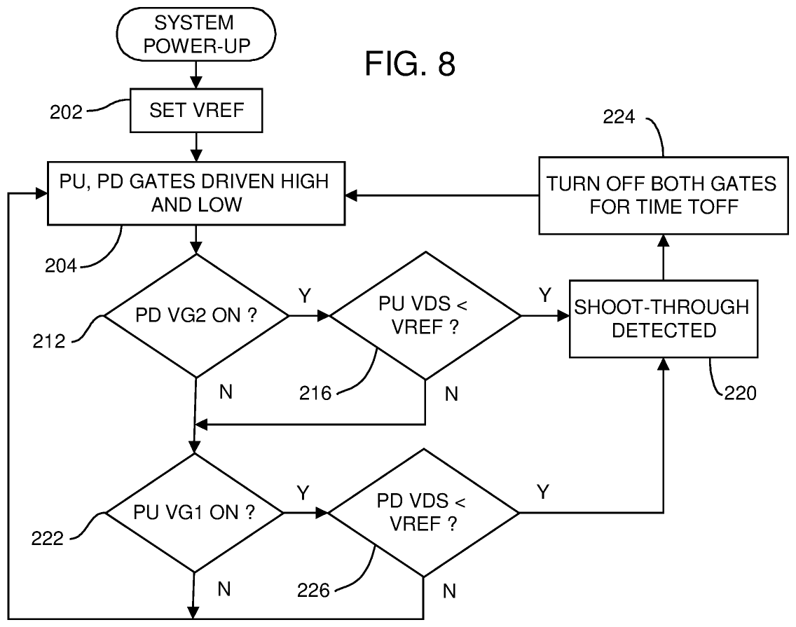

FIG. 8 is a flowchart of detection of a falling drain-source voltage on the OFF transistor to turn off the ON transistor for short protection. After the system is powered up, VREF is set, step 202, such as by reading a programmable value in a programmable register, reading a logic state of an external option pin, or using a hardware option, to cause the VREF generator to generate a desired VREF.

During normal switching operations, step 204, G1 is driven high and G2 is driven low for Pull-Up (PU) mode, and G1 is driven low and G2 is driven high for Pull-Down (PD) mode. These modes are alternated depending on the data, such as PD mode being used to send a data 0 and PU mode being used for data 1.

During PD mode, G2 is on and VG2 is high, step 212, and VDS detector 102 (FIG. 5) examines VDS and comparator 104 compares the sensed VDS to VREF, step 216. Normally VDS of the OFF device, pull-up transistor 30, is more than VREF, and no short is detected.

When VDS on pull-up transistor 30 is less than VREF, step 216, a short or shoot-through is detected, step 220. Both G1 and G2 are driven low, step 224, to cut off the shoot-through current. G1 was already driven low but G2 was high for PD mode, so G2 transitions from high to low.

During PU mode, G1 is on and VG1 is high, step 222, and VDS detector 172 (FIG. 6) examines VDS2 and comparator 174 compares the sensed VDS2 to VREF, step 226. Normally VDS2 of the OFF device, pull-down transistor 32, is more than VREF, and no short is detected.

When VDS2 on pull-down transistor 32 is less than VREF, step 226, a short or shoot-through is detected, step 220. Both G1 and G2 are driven low, step 224, to cut off the shoot-through current. G2 was already driven low but G1 was high for PU mode, so G1 transitions from high to low.

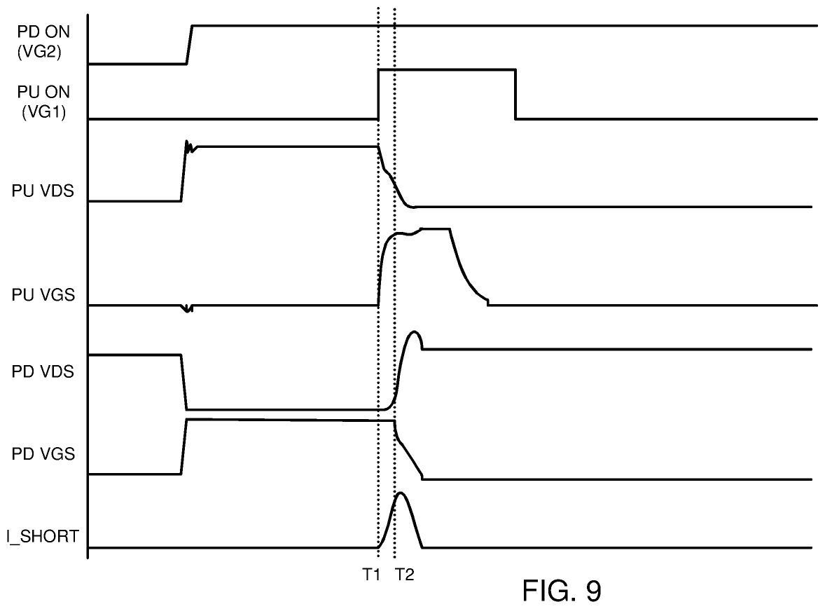

FIG. 9 is a waveform of operation of the short detection circuit. Pull-up transistor 32 turns on and PD mode starts when VG2 goes high. The gate-to-source voltage, PD VGS, goes high for pull-up transistor 32 which causes its drain and source to equalize and be driven to ground, causing PD VDS (VDS2) to fall to ground.

The other device, pull-down transistor 30, remains off since its gate VG1 is low, and PU VGS remains low. However, its source voltage, VOUT, is pulled to ground by pull-up transistor 32 being ON, so PU VDS rises as a large voltage difference forms across the OFF pull-up transistor 32.

At time T1, a simulated glitch occurs, causing VG1 to erroneously go high while VG2 is also ON. In the simulation, VG1 is pulsed on when VG2 is already on for PD mode. The high VG1 charges the gate of pull-up transistor 32, and PU VGS rapidly rises from T1 until T2. As current flows through the OFF pull-up transistor 32, the drain and source of pull-up transistor 32 equalize and PU VDS falls rapidly. At time T2 PU VDS falls below VREF, and FAULT is signaled. In this example, VREF is about half of the full PU VDS swing.

When FAULT is signaled at time T2, G2 is driven low to shut off the shoot-through current and turn the ON device OFF. PD VGS immediately drops lower and then continues to fall to ground. This starts to shut off pull-down transistor 30, causing its source and drain to disconnect, allowing PD VDS to rise. Also, as pull-down transistor 30 shuts off, the shoot-through current is blocked, so the short circuit current I_SHORT peaks just after T2 when FAULT was signaled.

In the simulation, PD ON is a driver control signal (such as DATAB) that can be an input to a buffer that drives VG2, and PU ON is another driver control signal (such as DATA) that can be an input to a buffer that drives VG1. In normal operation PU ON would never be pulsed high while PD is already ON, but for simulation PU ON is pulsed high to simulate a glitch or other event that would cause a short.

PU VGS later slowly falls to ground when VOUT is left floating when both pull-down transistor 30 and pull-up transistor 32 are OFF, and external circuitry pulls VOUT high.

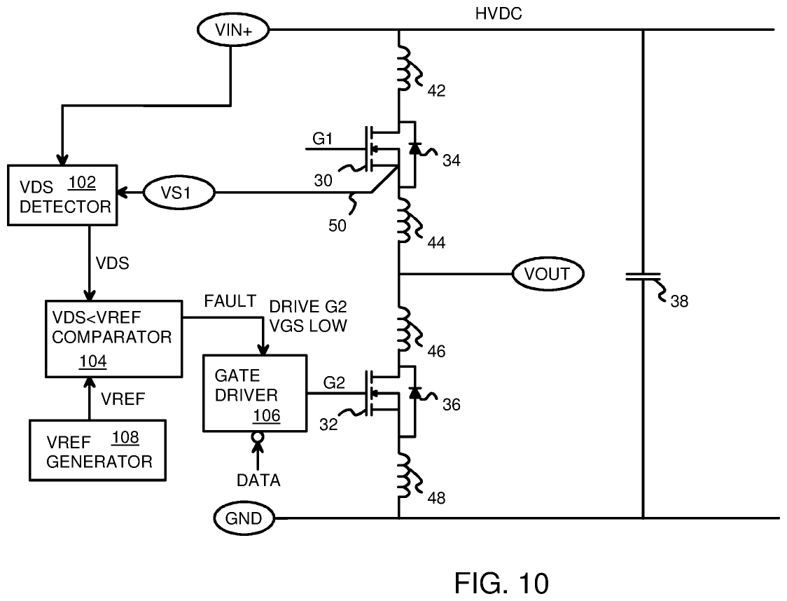

FIG. 10 is an alternative short detection circuit when a Kelvin drain is not available. Some devices have pull-up transistor 32 but only have a Kelvin source pin, but not a Kelvin drain pin. The package may provide pin VS1 that connects to Kelvin sensing path 50 to the source of pull-down transistor 30 but does not have Kelvin sensing path 54 to the drain of pull-down transistor 30.

Rather than connect to VD1, detector 102 can connect to VIN+. VIN+ can be used as an approximation of VD1 (FIG. 5). There will be an additional voltage drop due to inductor 42, so sensing will not be as accurate. VREF may need to be adjusted to account for the greater error in sensing. Detector 102 then generates VDS as VIN+−VS1, rather than VD1−VS1.

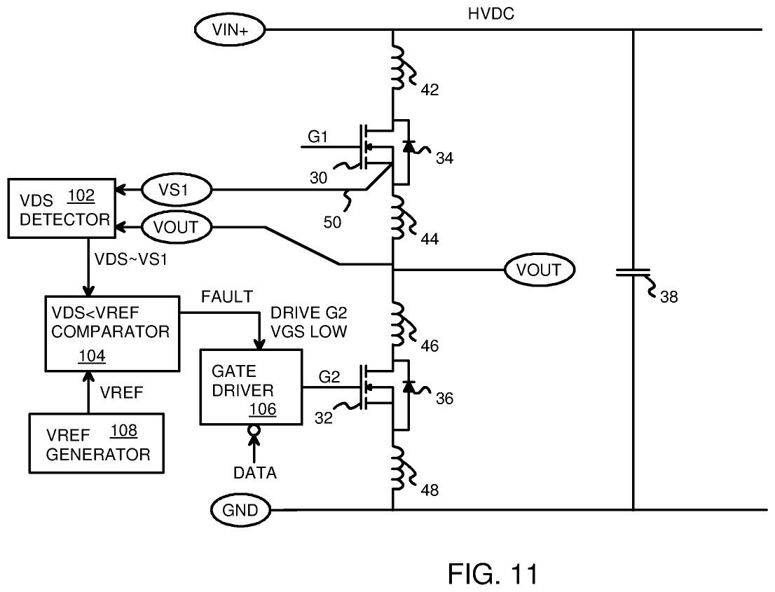

FIG. 11 is another alternative short detection circuit when a Kelvin drain is not available. Some devices have pull-up transistor 32 but only have a Kelvin source pin, but not a Kelvin drain pin. The package may provide pin VS1 that connects to Kelvin sensing path 50 to the source of pull-down transistor 30 but does not have Kelvin sensing path 54 to the drain of pull-down transistor 30.

Detector 102 connects to VS1 and VOUT in this alternative. VS1 is used rather than VD1 as the higher input to detector 102. For the lower input to detector 102, VOUT is used as an approximation of VS1 (FIG. 5). There will be an additional voltage drop due to inductor 44, so sensing will not be as accurate. VREF may need to be adjusted to account for the greater error in sensing. Detector 102 then generates VDS as VS1−VOUT, rather than VD1−VS1.

In normal operation, VS1−VOUT should be low when pull-down transistor 30 is OFF during PD mode. When shoot-through occurs, VS1−VOUT is high. The inputs to comparator 74 may be swapped to allow for inverse detection in this embodiment.

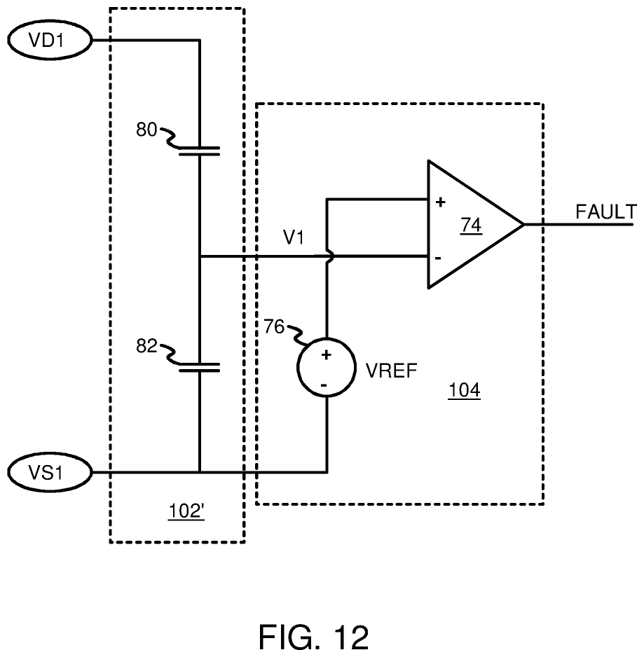

FIG. 12 shows a capacitor-divider detection circuit. High speed switching may benefit from capacitor dividers rather than resistor dividers. Detector 102′ is a voltage divider of capacitors 80, 82 that generate voltage V1 as a midpoint voltage between VD1 and VS1. For example, when the capacitances of capacitors 80, 82 are equal, then V1=(VD1−VS1)/2+VS1.

Comparator 104 applies midpoint voltage V1 to the inverting (−) input of comparator 74, while the non-inverting (+) input of comparator 74 receives VS1 shifted by reference voltage VREF, using reference voltage generator 76 to add VREF to VS1. Comparator 74 activates its output FAULT when (VS1+VREF) is greater than V1.

More generically, when the capacitance ratio C of capacitors 80, 82, and C=C80/(C80+C82), then:

VREF>(VD1−VS1)*C

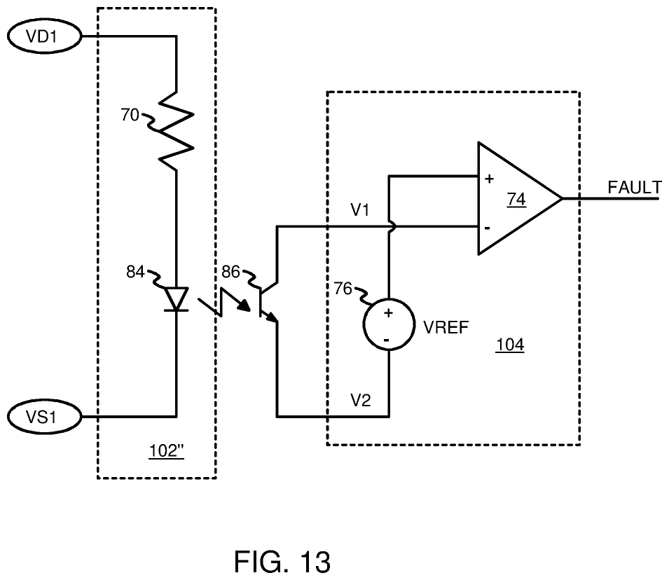

FIG. 13 shows an opto-isolated detection circuit. Detector 102′ has resistor 70 and diode 84 in series between VD1 and VS1. As current flows through diode 84, diode 84 emits light as a Light-Emitting Diode (LED). This light is absorbed by detector 86, which can be a transistor base that controls current flow and voltage V1 into comparator 74. Resistors or other components may be added.

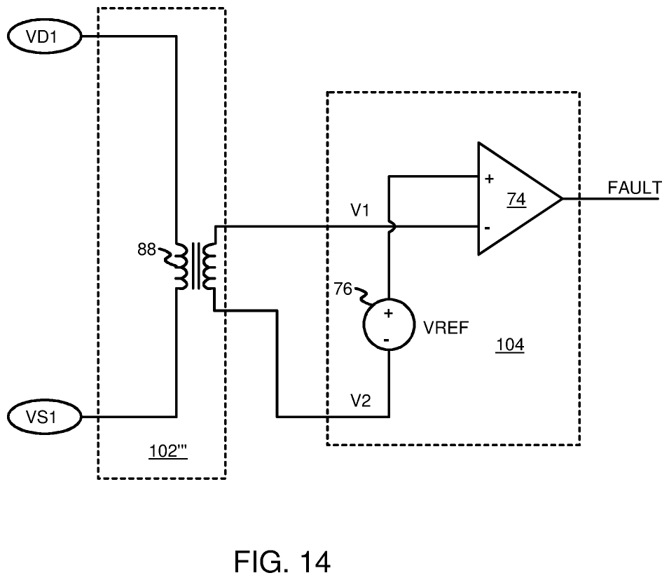

FIG. 14 shows a transformer-isolated detection circuit. Detector 102′″ has transformer 88 between VD1 and VS1. As current flows through the primary windings of transformer 88, a current is induced in the secondary windings of transformer 88. This secondary current flows into an input of comparator 74 to set V1. Resistors or other components may be added.

### Alternate Embodiments

Several other embodiments are contemplated by the inventors. For example, many combinations and variations of the methods, circuits, embodiments, and components are possible. The lower power supply may be ground or may be some other voltage or bus. There may be multiple power supply voltages.

Transistors may be used as resistors to limit current in some embodiments. Capacitors may be transistors with source and drains connected together as one terminal of the capacitor, and the gate as the other terminal. Variable capacitors or variable resistors may be substituted and constructed from multiple sub-components. The pre-driver or driver circuit that drives the gates of transistors 30, 32 may have various levels of buffers and include logic such as logic arrays or logic gates using NAND, NOR, AND, OR, XOR gates. Hysteresis or other delays may be added to DATA or DATAB to prevent both transistors 30, 32 from turning on at the same time during normal switching.

When both pull-down transistor 30 and pull-up transistor 32 are turned off, the fault signal will not be generated or can otherwise be disabled. Alternately, it may be assumed that a fault being signaled when both transistors should be turned off should not be disabled but be allowed to shut off the other transistor.

While n-channel transistors 30, 32 have been described, these could be standard silicon transistors or transistors with more exotic shapes such as FINFET or with various doping profiles, or may use more exotic materials such as Silicon Carbide (SiC) or Gallium Nitride (GaN).

While a single VREF has been described, there may be two VREFs, one for comparing to VDS from pull-up transistor 32, and another VREF2 for comparing to VDS2 from pull-down transistor 30.

The trigger voltage can be adjusted by adjusting VREF and R. VREF could be programmable, such as by being controlled by a programmable value in a programmable register. Alternately, resistor 72 could be a variable resistor, allowing R to be adjustable.

When the trigger voltage can be set by adjusting R, and an available voltage can be used for VREF, such as VIN+/2, then VREF generator 108 can be removed to further simplify the circuit.

VREF can be a fixed value or an adaptive value, such as based on the HVDC bus (VIN+). The voltage difference that corresponds to VREF could be 20% to 30% of the HVDC bus voltage. For applications such as Electric Vehicle (EV) charging, VIN+ can be 400 volts, so VREF can be more than 100 volts. In comparison, DESAT triggers at just a few volts. Thus, the invention can provide more than 100 volts of greater noise immunity than DESAT. Also, the filter needed to set the blanking time for DESAT is not needed with the invention, reducing cost and eliminating the time delay that the filter introduces for DESAT. With the invention the short protection is activated without waiting for the blanking delay or filter delay as with DESAT. Response time can be reduced from about 2.5 uS for DESAT to 0.4 uS with the invention.

Shoot-through could be caused by a variety of situations, such as noise coupled into the gate or source or into pre-driver nodes or other control nodes. Also logic errors or design errors or unexpected combinations of inputs or states might cause both pull-up and pull-down paths to be activated at the same time. FET damage or other component damage might also cause shoot-through.

Rather than turn off both PU and PD devices when FAULT is signaled, only the ON device could be turned off. Separate PU detection and PD turn off (FIG. 5) and PD detection and PU turn off (FIG. 6) could be provided, such as with separate hardware, or separate PU and PD detectors could be provided with FAULT only being generated in the proper state (FIG. 7), and then the FAULT signals OR'ed together and used to turn off both gates or only the ON gate. Real-time cross checking could be provided.

Steps in the flow of FIG. 8 may be processed in a different sequence or simultaneously. For example, steps 216, 226 may be performed continuously by hardware and then either the PU or PD compare result (fault signal) selected depending on whether PU or PD mode is currently active. After a fault has been detected, and the shoot-through current is stopped, normal operation could resume after a period of time, such as a delay that turns off the fault signal.

The FAULT signal could drive a NOR gate in the gate drivers that causes the gate voltage to be driven to ground when FAULT is high, and otherwise lets the data pass through to the gate. Many other logic gates and implementations are possible for various gate drivers circuits and implementations, such as gate drivers 106, 176.

While n-channel transistors have been described, p-channel transistors could be substituted and enabling voltages and the reference voltage adjusted. Depletion rather than enhancement transistors could be substituted. While pull-down transistor 30 and pull-up transistor 32 have been described as being of the same polarity, pull-up transistor 32 could be p-channel while pull-down transistor 30 could be n-channel, or vice-versa.

Although pins have been mentioned, these pins may be package pads rather than package pins, or package leads, or other connectors. The term pin is used generically to refer to any package electrical connector.

While the detection circuit could be external to the device package of pull-down transistor 30 and pull-up transistor 32, the detection circuit could also be integrated into the same package, and VD1, VS1, etc. can be internal nodes rather than external pins of the package. Pull-down transistor 30 and pull-up transistor 32 could be in separate packages or in the same package, even with other transistors or circuits. Many partitionings and integrations and arrangements are possible.

More complex buffers, level shifters, or other components could be substituted or added. Inversions could be added at various locations. Hysteresis of other delays and output wave shaping could be added. Rather than use CMOS inverters, other kinds of buffer circuits, selectors, or muxes may be used.

Different transistor, capacitor, resistor, and other device sizes can be used, and various layout arrangements can be used, such as multi-leg, ring, doughnut or irregular-shape transistors. Currents can be positive or negative currents and flow in either direction. Many second and third order circuit effects may be present and may be significant, especially for smaller device sizes. A circuit simulation may be used to account for these secondary factors during design.

Devices may be implemented using n-channel, p-channel, or bipolar transistors, or junctions within these transistors. The gate lengths and spacings can be increased to provide better protection from damage.

Many variations of IC semiconductor manufacturing processes are possible. Various materials may be used. Additional process steps may be added, such as for additional metal layers or for other transistor types or modification of standard complementary metal-oxide-semiconductor (CMOS) transistors when the transistors are integrated onto a larger device. While complementary metal-oxide-semiconductor (CMOS) transistors have been described, other kinds of transistors could be substituted for some embodiments, such as n-channel only, p-channel only when the output swing can be limited, or various alternate transistor technologies such as Bipolar or BiCMOS. The CMOS process may be a Fin Field-Effect Transistor (FinFET) process.

Terms such as up, down, above, under, horizontal, vertical, inside, outside, are relative and depend on the viewpoint and are not meant to limit the invention to a particular perspective. Devices may be rotated so that vertical is horizontal and horizontal is vertical, so these terms are viewer dependent.

The background of the invention section may contain background information about the problem or environment of the invention rather than describe prior art by others. Thus inclusion of material in the background section is not an admission of prior art by the Applicant.

Any methods or processes described herein are machine-implemented or computer-implemented and are intended to be performed by machine, computer, or other device and are not intended to be performed solely by humans without such machine assistance. Tangible results generated may include reports or other machine-generated displays on display devices such as computer monitors, projection devices, audio-generating devices, and related media devices, and may include hardcopy printouts that are also machine-generated. Computer control of other machines is another tangible result.

Any advantages and benefits described may not apply to all embodiments of the invention. When the word “means” is recited in a claim element, Applicant intends for the claim element to fall under 35 USC Sect. 112, paragraph 6. Often a label of one or more words precedes the word “means”. The word or words preceding the word “means” is a label intended to ease referencing of claim elements and is not intended to convey a structural limitation. Such means-plus-function claims are intended to cover not only the structures described herein for performing the function and their structural equivalents, but also equivalent structures. For example, although a nail and a screw have different structures, they are equivalent structures since they both perform the function of fastening. Claims that do not use the word “means” are not intended to fall under 35 USC Sect. 112, paragraph 6. Signals are typically electronic signals, but may be optical signals such as can be carried over a fiber optic line.

The foregoing description of the embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A short-current protection method for protecting a pull-up transistor and a pull-down transistor in series comprising:
sensing as an OFF drain-to-source voltage a drain-to-source voltage of the pull-up transistor when the pull-up transistor is turned OFF and the pull-down transistor is turned ON;
sensing as the OFF drain-to-source voltage a drain-to-source voltage of the pull-down transistor when the pull-down transistor is turned OFF and the pull-up transistor is turned ON;
comparing the OFF drain-to-source voltage to a reference voltage and signaling a fault when the OFF drain-to-source voltage is below the reference voltage; and
when the fault is signaled, disabling an ON transistor by driving a disabling voltage onto a gate of the ON transistor, wherein the ON transistor is the pull-up transistor when the pull-up transistor is turned ON and the pull-down transistor is turned OFF, and wherein the ON transistor is the pull-down transistor when the pull-down transistor is turned ON and the pull-up transistor is turned OFF,
whereby the ON transistor is turned off by the fault signal that is detected by the OFF drain-to-source voltage falling below the reference voltage.

2. The short-current protection method of claim 1 wherein the OFF drain-to-source voltage falls below the reference voltage when noise causes a gate voltage to turn on an OFF transistor that is otherwise turned off by logic signals;
wherein the OFF transistor is the pull-up transistor when the pull-up transistor is turned OFF and the pull-down transistor is turned ON by logic signals causing a first gate driver to drive an active signal to a gate of the pull-down transistor and causing a second gate driver to drive an inactive signal to a gate of the pull-up transistor;
wherein the OFF transistor is the pull-down transistor when the pull-down transistor is turned OFF and the pull-up transistor is turned ON by logic signals causing the second gate driver to drive the active signal to the gate of the pull-up transistor and causing the first gate driver to drive the inactive signal to the gate of the pull-down transistor.

3. The short-current protection method of claim 2 further comprising:
setting the reference voltage to a voltage between a power voltage applied to a drain of the pull-up transistor and a lower supply voltage applied to a source of the pull-down transistor.

4. The short-current protection method of claim 2 further comprising:
setting the reference voltage to at least 100 volts but not more than 100 volts below a power voltage applied to a drain of the pull-up transistor when the power voltage is at least 200 volts;
wherein 100 volts of noise immunity is provided to prevent false triggering of the fault signal.

5. The short-current protection method of claim 2 further comprising:
setting the reference voltage to a fraction of a power voltage applied to a drain of the pull-up transistor, wherein the fraction is between 0.2 and 0.4 of the power voltage.

6. The short-current protection method of claim 2 wherein a drain of the pull-up transistor has a high-current path to a power bus, and a second path from the drain to a Kelvin drain output;
wherein a source of the pull-up transistor has a high-current path to an output bus and to a drain of the pull-down transistor, and a second path from the source to a Kelvin source output;
wherein sensing as an OFF drain-to-source voltage the drain-to-source voltage of the pull-up transistor when the pull-up transistor is turned OFF and the pull-down transistor is turned ON further comprises:
sensing a sensed drain voltage of the Kelvin drain output and applying the sensed drain voltage to a first input of a divider;
sensing a sensed source voltage of the Kelvin source output and applying the sensed source voltage to a second input of the divider;
applying an output of the divider to a first input of a comparator, and applying the reference voltage to a second input of the comparator, and generating the fault signal as an output of the comparator.

7. A short-current protection circuit comprising:
a first transistor having a first gate receiving a first control signal, a first drain connected to a power bus, and a first source connected to an output;
a second transistor having a second gate receiving a second control signal, a second drain connected to the output, and a second source connected to a lower supply;
a first drain-source detector connected to the first drain and connected to the first source, for generating a first drain-source voltage;
a first comparator for comparing the first drain-source voltage to a reference voltage and generating a first fault signal when the first drain-source voltage is less than the reference voltage;
a first driver for generating the second control signal in response to a data signal, the first driver also receiving the first fault signal from the first comparator, the first driver driving a disabling voltage that disables the second transistor when the first fault signal is activated;
wherein short current through both the first transistor and the second transistor is shut off when the first drain-source voltage detected from the first transistor falls below the reference voltage causing the first driver to shut off the second transistor.

8. The short-current protection circuit of claim 7 further comprising:
a second drain-source detector connected to the second drain and connected to the second source, for generating a second drain-source voltage;
a second comparator for comparing the second drain-source voltage to a second reference voltage and generating a second fault signal when the second drain-source voltage is less than the second reference voltage;
a second driver for generating the first control signal in response to the data signal, the second driver also receiving the second fault signal from the second comparator, the second driver driving a disabling voltage that disables the first transistor when the second fault signal is activated;
wherein short current through both the first transistor and the second transistor is shut off when the second drain-source voltage detected from the second transistor falls below the second reference voltage causing the second driver to shut off the first transistor.

9. The short-current protection circuit of claim 8 wherein the first driver has logic hardware that, when the data signal represents a logic 0, drives the second control signal active when the first fault signal is not activated and drives the second control signal inactive when the first fault signal is activated;
wherein the second driver has logic hardware that, when the data signal represents a logic 1, drives the first control signal active when the second fault signal is not activated and drives the first control signal inactive when the second fault signal is activated;
wherein, in response to the data signal, the second driver turns on the first transistor to drive the output high when the first fault signal is not activated;
wherein, in response to the data signal, the first driver turns on the second transistor to drive the output low when the second fault signal is not activated.

10. The short-current protection circuit of claim 9 further comprising:
a first source high-current path from the first source to the output;
a first source parasitic inductor on the first source high-current path;
a first source Kelvin sensing path from the first source to the first drain-source detector;
wherein the first drain-source detector avoids sensing a voltage drop across the first source parasitic inductor by sensing through the first source Kelvin sensing path.

11. The short-current protection circuit of claim 10 further comprising:
a first drain high-current path from the first drain to the power bus;
a first drain parasitic inductor on the first drain high-current path;
a first drain Kelvin sensing path from the first drain to the first drain-source detector;
wherein the first drain-source detector avoids sensing a voltage drop across the first drain parasitic inductor by sensing through the first drain Kelvin sensing path.

12. The short-current protection circuit of claim 11 further comprising:
a second source high-current path from the second source to the lower supply;
a second source parasitic inductor on the second source high-current path;
a second source Kelvin sensing path from the second source to the second drain-source detector;
wherein the second drain-source detector avoids sensing a voltage drop across the second source parasitic inductor by sensing through the second source Kelvin sensing path;
a second drain high-current path from the second drain to the output;
a second drain parasitic inductor on the second drain high-current path;
a second drain Kelvin sensing path from the second drain to the second drain-source detector;
wherein the second drain-source detector avoids sensing a voltage drop across the second drain parasitic inductor by sensing through the second drain Kelvin sensing path.

13. The short-current protection circuit of claim 9 wherein the first drain-source detector further comprises:
a first upper resistor connected between the first drain-source voltage and the first drain;
a first lower resistor connected between the first drain-source voltage and the first source;
wherein the second drain-source detector further comprises:
a second upper resistor connected between the second drain-source voltage and the second drain;
a second lower resistor connected between the second drain-source voltage and the second source;
whereby voltage dividers generate the first drain-source voltage and the second drain-source voltage.

14-16. (canceled)

17. The short-current protection circuit of claim 9 wherein the reference voltage is a fraction of a voltage of the power bus;
wherein the fraction is between 0.2 and 0.5 and the voltage of the power bus is at least 100 volts;
wherein the reference voltage is at least 50 volts lower than a maximum voltage of the first drain-source voltage, wherein at least 50 volts of noise immunity is provided to prevent erroneous activation of the first fault signal.

18. The short-current protection circuit of claim 9 wherein the reference voltage is programmable.

19. The short-current protection circuit of claim 9 wherein the reference voltage and the second reference voltage are a same voltage.

20. A control method for controlling a circuit with an upper transistor and a lower transistor to stop short-circuit currents comprising:
receiving a data signal;
when the data signal is logic 0, activating a lower driver circuit to drive an enabling voltage onto a lower gate of the lower transistor to cause the lower transistor to conduct current from a lower drain to a lower source,
when the data signal is a logic 1, activating the lower driver circuit to drive a disabling voltage onto the lower gate to turn off the lower transistor;
when the data signal is logic 1, activating an upper driver circuit to drive an enabling voltage onto an upper gate of the upper transistor to cause the upper transistor to conduct current from an upper drain to an upper source,
when the data signal is a logic 0, activating the upper driver circuit to drive a disabling voltage onto the upper gate to turn off the upper transistor;
wherein an output is connected to the lower drain and to the upper source;
wherein the upper drain is connected to an upper power supply;
wherein the lower source is connected to a lower power supply;
when the data signal is logic 0, detecting a short circuit condition by sensing an upper drain-source voltage between the upper drain and the upper source and comparing the upper drain-source voltage to a first reference voltage and signaling an upper fault when the upper drain-source voltage is less than the first reference voltage;
when the data signal is logic 0, ending the short circuit condition when the upper fault is signaled by forcing the lower driver circuit to drive the disabling voltage onto the lower gate to turn off the lower transistor;
when the data signal is logic 1, detecting a short circuit condition by sensing a lower drain-source voltage between the lower drain and the lower source and comparing the lower drain-source voltage to a second reference voltage and signaling a lower fault when the lower drain-source voltage is less than the second reference voltage;
when the data signal is logic 1, ending the short circuit condition when the lower fault is signaled by forcing the upper driver circuit to drive the disabling voltage onto the upper gate to turn off the upper transistor;
whereby detection and protection are performed on different transistors to stop short current flowing through both transistors.
